(19) United States
(12) Patent Application Publication
(10) Pub. No.: US 2024/0194839 A1
(43) Pub. Date: Jun. 13, 2024

(54) SHAPE-SHIFTING, OPTICAL-ELECTRICAL ADJUSTMENT AND PROTECTION STRETCH-SEAL STRUCTURE DESIGN

(71) Applicant: General Interface Solution Limited, Miaoli County (TW)

(72) Inventors: CHIA-MING FAN, Miaoli County (TW); WEN-YOU LAI, Miaoli County (TW); HSIEN-YING CHOU, Miaoli County (TW); PO-LUN CHEN, Miaoli County (TW); CHUN-TA CHEN, Miaoli County (TW); PO-CHING LIN, Miaoli County (TW)

(21) Appl. No.: 18/080,829

(22) Filed: Dec. 14, 2022

(30) Foreign Application Priority Data
Dec. 12, 2022 (CN) 202211590339.2

(51) Int. Cl. H01L 33/56; H01L 25/16; H01L 33/58

(52) U.S. Cl. CPC H01L 33/56; H01L 25/167; H01L 33/58

(57) ABSTRACT

A micro light-emitting diode display is based on a conventional micro light-emitting diode display and includes at least one electrically conductive material layer or at least one functional material added to an encapsulation layer, so as to achieve antistatic effect. The micro light-emitting diode display solves the problem that the conventional micro light-emitting diode display is easily damaged by electrostatic breakdown.

### REFERENCE TO RELATED APPLICATIONS

The present application is based on, and claims priority from, China Application Serial Number 202211590339.2 filed Dec. 12, 2022, the disclosure of which is hereby incorporated by reference herein in its entirety.

### FIELD OF THE INVENTION

The present invention relates to a display, and more particularly to a micro light-emitting diode display.

### BACKGROUND OF THE INVENTION

In general, in the manufacturing process of a micro light-emitting diode display, the micro light-emitting diode display may be damaged by static electricity. The manufacturing process of the micro light-emitting diode display as well as subsequent procedures, such as feeding/discharging materials, transportation, movement of a robot arm, laser cutting, roller transmission, protective film peeling and bonding and so on, will cause charge accumulation. When the charge accumulation reaches a critical value, it will cause dielectric breakdown to generate electrostatic discharge. This will damage the micro light-emitting diode display and cause malfunction. For example, in the process of preparing the micro light-emitting diode display, because the support layer is generally a plastic film material, the support layer is easy to accumulate charges. The flexible thin film transistor array module is affected by the accumulated static charges of the support layer. As a result, the gate of the thin film transistor in the flexible thin film transistor array module needs a larger positive voltage to turn off the thin film transistor. Therefore, the threshold voltage (Vth) will be shifted in the Id-Vg characteristic curve, which will affect the switching function of the thin film transistor. When the charge accumulation of the support layer reaches a critical value to cause electrostatic discharge, the thin film transistor may be damaged, resulting in failure of the switching function of the thin film transistor. In addition, the surface of the encapsulation layer of the micro light-emitting diode display is prone to charge accumulation. This is one of the causes of electrostatic discharge to damage the micro light-emitting diode display. When charges accumulate on the surface of the encapsulation layer, dust will be adsorbed on the surface of the encapsulation layer. When the charge accumulation reaches a critical value, it will cause dielectric breakdown to generate electrostatic discharge. This will damage the micro light-emitting diode display and cause malfunction.

Therefore, how to prevent the charge accumulation of the micro light-emitting diode display and avoid the damage of the micro light-emitting diode display caused by the charge accumulation to cause malfunction is a problem to be solved.

### SUMMARY OF THE INVENTION

The primary object of the present invention is to provide a micro light-emitting diode display, which can solve the problem that the charge accumulation of the micro light-emitting diode display causes damage to the micro light-emitting diode display and leads to malfunction.

According to one aspect of the present invention, a micro light-emitting diode display comprises a support layer, an optical adhesive layer, a flexible substrate, a flexible thin film transistor array module, and an encapsulation layer. The optical adhesive layer is disposed on an upper surface of the support layer. The flexible substrate is disposed on an upper surface of the optical adhesive layer. The flexible thin film transistor array module is disposed on an upper surface of the flexible substrate. The encapsulation layer covers an upper surface of the flexible thin film transistor array module. The micro light-emitting diode display further comprises at least one electrically conductive material layer disposed on one side away from the flexible thin film transistor array module.

In one embodiment of the present invention, the electrically conductive material layer is disposed between the optical adhesive layer and the flexible substrate, and the electrically conductive material layer has a sheet resistance of 10-10⁶Ω/□.

In one embodiment of the present invention, the electrically conductive material layer is disposed between the support layer and the optical adhesive layer, and the electrically conductive material layer has a sheet resistance of 10-10⁶Ω/□.

In one embodiment of the present invention, the electrically conductive material layer is disposed on part of the upper surface of the support layer, and the electrically conductive material layer has a sheet resistance of 10⁶-10¹²Ω/□.

In one embodiment of the present invention, the at least one electrically conductive material layer includes two electrically conductive material layers, i.e., a first electrically conductive material layer and a second electrically conductive material layer. The first electrically conductive material layer is disposed on a lower surface of the support layer. The second electrically conductive material layer is disposed between the support layer and the optical adhesive layer. The first electrically conductive material layer and the second electrically conductive material layer each have a sheet resistance of 10⁶-10¹²Ω/□.

In one embodiment of the present invention, the electrically conductive material layer is made of indium tin oxide, aluminum-doped zinc oxide (AZO), fluorine-doped tin oxide (FTO), silver nanowire, carbon nanotube, electrically conductive polymer or a combination thereof. The electrically conductive polymer may be poly(3,4-ethylenedioxythiophene) polystyrene sulfonate (PEDOT:PSS).

According to another aspect of the present invention, a micro light-emitting diode display comprises a support layer, an optical adhesive layer, a flexible substrate, a flexible thin film transistor array module, and an encapsulation layer. The optical adhesive layer is disposed on an upper surface of the support layer. The flexible substrate is disposed on an upper surface of the optical adhesive layer. The flexible thin film transistor array module is disposed on an upper surface of the flexible substrate. The encapsulation layer covers an upper surface of the flexible thin film transistor array module. The encapsulation layer includes an encapsulation material and at least one functional material. The functional material is an electrically conductive material, an antistatic material, a high dielectric material or a combination thereof.

In one embodiment of the present invention, the high dielectric material refers to a dielectric material with a relative permittivity between 1 and 1000, preferably, a dielectric material with a relative permittivity between 10 and 100

In one embodiment of the present invention, when the functional material is the electrically conductive material, the high dielectric material or a combination thereof, the functional material is granular, and the functional material has a particle size between 1 and 1000 nanometers.

In one embodiment of the present invention, the functional material is the antistatic material, and the antistatic material is solid or liquid.

In one embodiment of the present invention, the functional material has a refractive index greater than 2.

In one embodiment of the present invention, the material of the metal wires may be a stretch-proof metal. The stretch-proof metal may be gold, silver, copper, molybdenum, or aluminum.

In one embodiment of the present invention, the metal wires may be pre-strained, so as to offset the length change caused by stretching.

In one embodiment of the present invention, the material of the flexible substrate may be polyimide (PI), polyethylene naphthalate (PEN), polyethylene terephthalate (PET), or a combination thereof.

In one embodiment of the present invention, the light-emitting elements may be light-emitting diodes, mini light-emitting diodes, micro light-emitting diodes or organic light-emitting diodes (OLED).

In one embodiment of the present invention, the functional material may be a metal material, graphene, carbon nanotubes, carbon black, electrically conductive polymer, metal oxide or a mixture thereof.

In one embodiment of the present invention, the metal material may be gold, silver, copper, molybdenum or other metals.

In one embodiment of the present invention, the electrically conductive polymer may be poly(3,4-ethylenedioxythiophene) polystyrene sulfonate.

In one embodiment of the present invention, the metal oxide may be zirconium oxide (ZrO₂), indium oxide (In₂O₃), zinc oxide (ZnO), tin oxide (SnO₂), titanium oxide (TiOx).

In one embodiment of the present invention, the antistatic material may be cationic antistatic agent, anionic antistatic agent or amphoteric antistatic agent.

In one embodiment of the present invention, the high dielectric material may be zinc oxide, silicon dioxide, titanium dioxide, zirconium oxide, barium sulfate, barium titanate, calcium carbonate or a mixture thereof.

In one embodiment of the present invention, the encapsulation layer is a single-layer structure. The encapsulation layer includes the encapsulation material and the functional material. The encapsulation layer has a surface resistance of 10⁴-10¹¹Ω.

In one embodiment of the present invention, the encapsulation layer is a double-layer structure, including a first encapsulation layer and a second encapsulation layer. The second encapsulation layer is disposed on an upper surface of the first encapsulation layer. The material of the first encapsulation layer is the encapsulation material. The material of the second encapsulation layer includes the encapsulation material and the functional material. The encapsulation layer has a surface resistance of 10⁴-10¹¹Ω.

In one embodiment of the present invention, the encapsulation layer is a double-layer structure, including a first encapsulation layer and a second encapsulation layer. The second encapsulation layer is disposed on an upper surface of the first encapsulation layer. Each of the material of the first encapsulation layer and the material of the second encapsulation layer is composed of the encapsulation material and the functional material. The functional material of the first encapsulation layer is defined as a first functional material. The functional material of the second encapsulation layer is defined as a second functional material. The first functional material and the second functional material are different materials. The encapsulation layer has a surface resistance of 10⁴-10¹¹Ω.

In one embodiment of the present invention, when the encapsulation layer is a single-layer structure, the material of the encapsulation layer includes the encapsulation material and the functional material, and the encapsulation layer has a surface resistance of 10⁴-10¹¹Ω. The encapsulation layer has a refractive index between 1.6 and 2.0.

In one embodiment of the present invention, when the encapsulation layer is a double-layer structure, including a first encapsulation layer and a second encapsulation layer, the second encapsulation layer is disposed on an upper surface of the first encapsulation layer, the material of the first encapsulation layer is the encapsulation material, and the material of the second encapsulation layer includes the encapsulation material and the functional material. When the surface resistance of the encapsulation layer is 10⁴-10¹¹Ω, the first encapsulation layer has a refractive index between 1.4 and 1.7, and the second encapsulation layer has a refractive index between 1.6 and 2.0.

In one embodiment of the present invention, when the encapsulation layer is a double-layer structure, including a first encapsulation layer and a second encapsulation layer, the second encapsulation layer is disposed on an upper surface of the first encapsulation layer, the material of the first encapsulation layer is the encapsulation material, and the material of the second encapsulation layer includes the encapsulation material and the functional material. When the surface resistance of the encapsulation layer is 10⁴-10¹¹Ω, the refractive index of the first encapsulation layer is greater than the refractive index of the second encapsulation layer.

In one embodiment of the present invention, when the encapsulation layer is a double-layer structure, including a first encapsulation layer and a second encapsulation layer, the second encapsulation layer is disposed on an upper surface of the first encapsulation layer, wherein each of the material of the first encapsulation layer and the material of the second encapsulation layer is composed of the encapsulation material and the functional material, the functional material of the first encapsulation layer is defined as a first functional material, the functional material of the second encapsulation layer is defined as a second functional material, and the first functional material and the second functional material are different materials. When the surface resistance of the encapsulation layer is 10⁴-10¹¹Ω, the first encapsulation layer and the second encapsulation layer each have a refractive index between 1.6 and 2.0.

In one embodiment of the present invention, when the encapsulation layer is a double-layer structure, including a first encapsulation layer and a second encapsulation layer, the second encapsulation layer is disposed on an upper surface of the first encapsulation layer, wherein each of the material of the first encapsulation layer and the material of the second encapsulation layer is composed of the encapsulation material and the functional material, the functional material of the first encapsulation layer is defined as a first functional material, the functional material of the second encapsulation layer is defined as a second functional material, and the first functional material and the second functional material are different materials. When the surface resistance of the encapsulation layer is 10⁴-10¹¹Ω, the refractive index of the first encapsulation layer is greater than the refractive index of the second encapsulation layer.

In one embodiment of the present invention, when the encapsulation layer is a single-layer structure, the material of the encapsulation layer includes the encapsulation material and the functional material. When the surface resistance of the encapsulation layer is 10⁴-10¹¹Ω, the encapsulation layer includes 0.01-10 wt % the functional material.

In one embodiment of the present invention, when the encapsulation layer is a double-layer structure, including a first encapsulation layer and a second encapsulation layer, the second encapsulation layer is disposed on an upper surface of the first encapsulation layer, the material of the first encapsulation layer is the encapsulation material, and the material of the second encapsulation layer includes the encapsulation material and the functional material. When the surface resistance of the encapsulation layer is 10⁴-10¹¹Ω, the second encapsulation layer includes 0.01-10 wt % the functional material.

In one embodiment of the present invention, when the encapsulation layer is a double-layer structure, including a first encapsulation layer and a second encapsulation layer, the second encapsulation layer is disposed on an upper surface of the first encapsulation layer, wherein each of the material of the first encapsulation layer and the material of the second encapsulation layer is composed of the encapsulation material and the functional material, the functional material of the first encapsulation layer is defined as a first functional material, the functional material of the second encapsulation layer is defined as a second functional material, and the first functional material and the second functional material are different materials. When the surface resistance of the encapsulation layer is 10⁴-10¹¹Ω, the first encapsulation layer includes 0.01-10 wt % the first functional material, and the second encapsulation layer includes 0.01-10 wt % the second functional material.

In one embodiment of the present invention, the encapsulating material may be thermosetting resin or photocurable resin, such as epoxy resin, silicone resin, silicone, acrylic resin or a mixture thereof.

In one embodiment of the present invention, the flexible thin film transistor array module includes a plurality of thin film transistor regions, a plurality of metal wires, and a plurality of light-emitting elements. The plurality of thin film transistor regions are electrically connected with the plurality of metal wires. The plurality of light-emitting elements are correspondingly disposed on the upper surfaces of the plurality of thin film transistor regions. Each thin film transistor region includes at least one thin film transistor and at least one storage capacitor. The light-emitting element, the thin film transistor and the storage capacitor located in the same thin film transistor region are electrically connected to each other.

To sum up, the micro light-emitting diode display provided by the present invention can prevent the accumulation of static electricity and solve the problem that the conventional micro light-emitting diode display is susceptible to electrostatic breakdown, causing component abnormalities or component damage.

### BRIEF DESCRIPTION OF THE DRAWINGS

FIG. 1 is a schematic view of a conventional micro light-emitting diode display;

FIG. 2 is a schematic view of a first embodiment of the present invention;

FIG. 3 is a schematic view of a second embodiment of the present invention;

FIG. 4 is a schematic view of a third embodiment of the present invention;

FIG. 5 is a schematic view of a fourth embodiment of the present invention;

FIG. 6 is a schematic view of a fifth embodiment of the present invention;

FIG. 7 is a schematic view of another implementation of the fifth embodiment of the present invention;

FIG. 8 is a schematic view of a sixth embodiment of the present invention;

FIG. 9 is a schematic view of the sixth embodiment of the present invention, wherein both the upper surface of the first encapsulation layer and the upper surface of the second encapsulation layer include a plurality of microstructures;

FIG. 10 is a schematic view of the sixth embodiment of the present invention, wherein the upper surface of the first encapsulation layer includes a plurality of microstructures and the second encapsulation layer is a leveling layer;

FIG. 11 is a schematic view of a seventh embodiment of the present invention;

FIG. 12 is a schematic view of the seventh embodiment of the present invention, wherein both the upper surface of the first encapsulation layer and the upper surface of the second encapsulation layer include a plurality of microstructures; and

FIG. 13 is a schematic view of the seventh embodiment of the present invention, wherein the upper surface of the first encapsulation layer includes a plurality of microstructures and the second encapsulation layer is a leveling layer.

### DETAILED DESCRIPTION OF THE PREFERRED EMBODIMENTS

Embodiments of the present invention will now be described, by way of example only, with reference to the accompanying drawings.

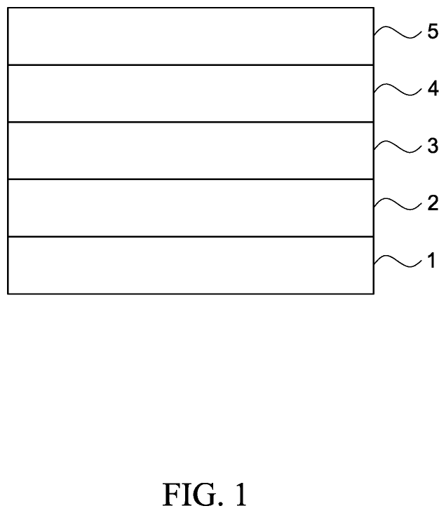

Referring to FIG. 1, a micro light-emitting diode display comprises a support layer 1, an optical adhesive layer 2, a flexible substrate 3, a flexible thin film transistor array module 4, and an encapsulation layer 5. The optical adhesive layer 2 is disposed on the upper surface of the support layer 1. The flexible substrate 3 is disposed on the upper surface of the optical adhesive layer 2. The flexible thin film transistor array module 4 is disposed on the upper surface of the flexible substrate 3. The encapsulation layer 5 covers the upper surface of the flexible thin film transistor array module 4. The flexible thin film transistor array module 4 includes a plurality of thin film transistor regions, a plurality of metal wires, and a plurality of light-emitting elements 40. The plurality of thin film transistor regions are electrically connected with the plurality of metal wires. The plurality of light-emitting elements 40 are correspondingly disposed on the upper surfaces of the plurality of thin film transistor regions. Each thin film transistor region includes at least one thin film transistor and at least one storage capacitor. The light-emitting element 40, the thin film transistor and the storage capacitor located in the same thin film transistor region are electrically connected to each other, which is a conventional structure.

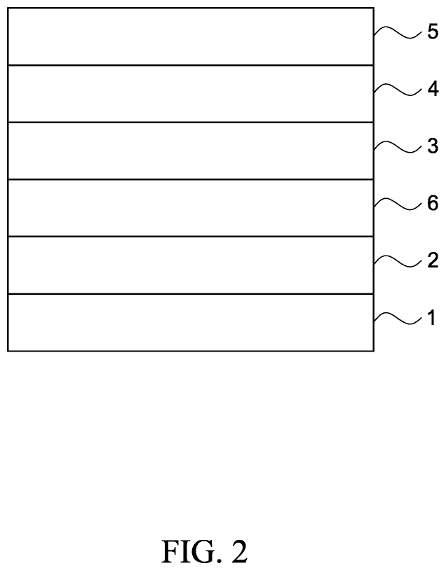

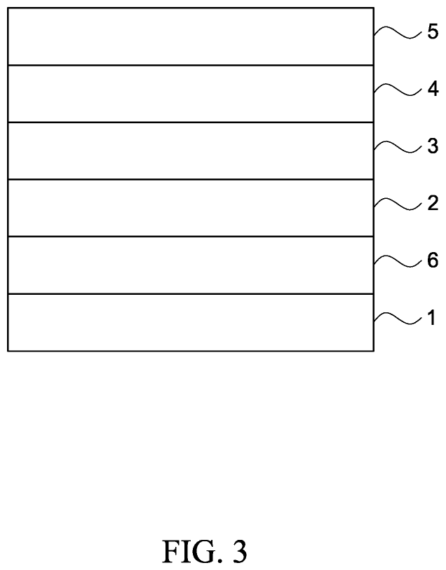

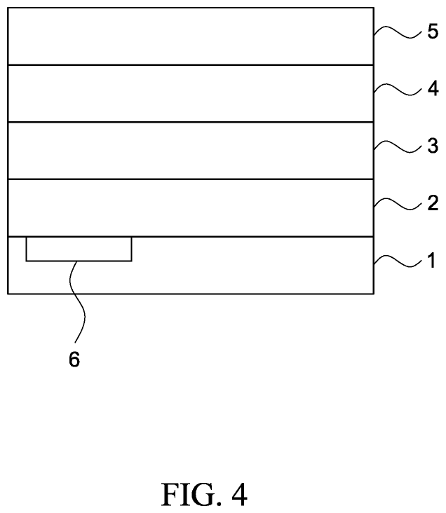

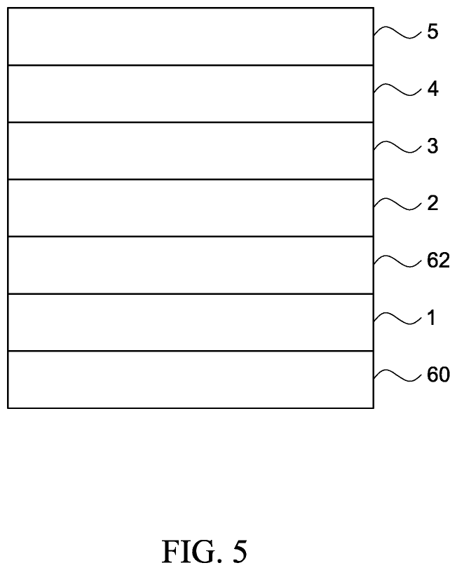

Please refer to FIG. 2, FIG. 3, FIG. 4 and FIG. 5. The present invention provides a micro light-emitting diode display, which is based on a conventional micro light-emitting diode display and further comprises at least one electrically conductive material layer 6. The at least one electrically conductive material layer 6 is disposed on one side away from the flexible thin film transistor array module 4. The electrically conductive material layer 6 of the present invention is configured to lead out the charges accumulated in the support layer 1 to dissipate the static electricity, so as to protect the flexible thin film transistor array module 4.

Referring to FIG. 2, in a first embodiment of the present invention, the micro light-emitting diode display comprises one electrically conductive material layer 6. The electrically conductive material layer 6 is disposed between the optical adhesive layer 2 and the flexible substrate 3. Therefore, the electrically conductive material layer 6 is disposed on the upper surface of the optical adhesive layer 2, and the flexible substrate 3 is disposed on the upper surface of the electrically conductive material layer 6. The sheet resistance of the electrically conductive material layer 6 is 10-10⁶Ω/□. The electrically conductive material layer 6 has the effect of electrostatic shielding, so as to prevent the charges accumulated in the support layer 1 from affecting the flexible thin film transistor array module 4 above the flexible substrate 3.

Referring to FIG. 3, in a second embodiment of the present invention, the micro light-emitting diode display comprises one electrically conductive material layer 6. The electrically conductive material layer 6 is disposed between the support layer 1 and the optical adhesive layer 2. Therefore, the electrically conductive material layer 6 is disposed on the upper surface of the support layer 1, and the optical adhesive layer 2 is disposed on the upper surface of the electrically conductive material layer 6. The sheet resistance of the electrically conductive material layer 6 is 10-10⁶Ω/□. The electrically conductive material layer 6 has the effect of electrostatic shielding, so as to prevent the charges accumulated in the support layer 1 from affecting the flexible thin film transistor array module 4 above the flexible substrate 3.

Referring to FIG. 4, in a third embodiment of the present invention, the micro light-emitting diode display comprises one electrically conductive material layer 6. The electrically conductive material layer 6 is formed on part of the upper surface of the support layer 1. The sheet resistance of the electrically conductive material layer 6 is 10⁶-10¹²Ω/□. The electrically conductive material layer 6 may be formed on part of the upper surface of the support layer 1 by screen printing, or the electrically conductive material layer 6 may be formed on part of the upper surface of the support layer 1 by a photolithography process, but not limited thereto. The electrically conductive material layer 6 formed on part of the upper surface of the support layer 1 is configured to lead out the charges accumulated in the support layer 1 and reduce the influence of the electrically conductive material layer 6 on the optical transmittance of the micro light-emitting diode display.

Referring to FIG. 5, in a fourth embodiment of the present invention, the micro light-emitting diode display includes two electrically conductive material layers 6, i.e., a first electrically conductive material layer 60 and a second electrically conductive material layer 62. The first electrically conductive material layer 60 is disposed on the lower surface of the support layer 1. The second electrically conductive material layer 62 is disposed between the support layer 1 and the optical adhesive layer 2. Therefore, the support layer 1 is disposed on the upper surface of the first electrically conductive material layer 60. The second electrically conductive material layer 62 is disposed on the upper surface of the support layer 1. The optical adhesive layer 2 is disposed on the upper surface of the second electrically conductive material layer 62. The sheet resistance of each of first electrically conductive material layer 60 and the second electrically conductive material layer 62 is 10⁶-10¹²Ω/□. The first electrically conductive material layer 60 and the second electrically conductive material layer 62 are configured to lead out the charges accumulated in the support layer 1, so as to prevent the charges accumulated in the support layer 1 from affecting the flexible thin film transistor array module 4 above the flexible substrate 3.

In the first, second, third and fourth embodiments of the present invention, the material of the electrically conductive material layer 6 may be indium tin oxide, aluminum-doped zinc oxide, fluorine-doped tin oxide, silver nanowire, carbon nanotube, electrically conductive polymer or a combination thereof. The electrically conductive polymer may be poly(3,4-ethylenedioxythiophene) polystyrene sulfonate.

The flexible substrate 3 of the conventional micro light-emitting diode display uses polyimide. The value of b* in the color difference value of the light generated by the micro light-emitting diode display is higher, which means that the color tone of the light is yellowish. When the electrically conductive material layer 6 of the micro light-emitting diode display is arranged in different way in the first embodiment, the second embodiment or the fourth embodiment and is an electrically conductive polymer, the adjustment of the color tone of the electrically conductive material layer 6 can reduce the value of b* in the color difference value of the light generated by the micro light-emitting diode display, so as to improve the problem that the color tone of the light generated by the conventional micro light-emitting diode display is yellowish.

The present invention provides a micro light-emitting diode display, which is based on a conventional micro light-emitting diode display. The improvement of the present invention is that the encapsulation layer 5 includes an encapsulation material and at least one functional material 7. The functional material 7 is an electrically conductive material, an antistatic material, a high dielectric material or a combination thereof. The functional material 7 is configured to reduce the surface resistance of the encapsulation layer 5, so that the surface resistance of the encapsulation layer 5 is 10⁴-10¹¹Ω, so as to achieve the antistatic effect. The high dielectric material refers to a dielectric material with a relative permittivity between 1 and 1000, preferably, a dielectric material with a relative permittivity between 10 and 100. The antistatic effect provided by the dielectric material with a relative permittivity between 10 and 100 is better than that of the dielectric material with a relative permittivity between 101 and 1000.

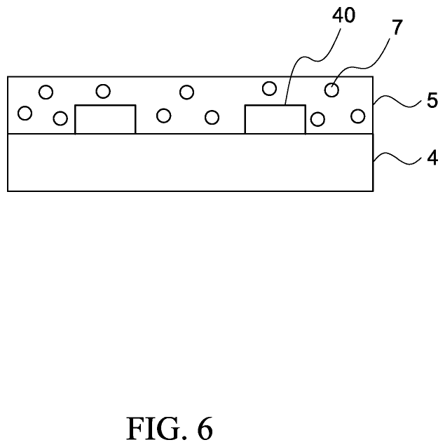

Referring to FIG. 6, in a fifth embodiment of the present invention, the encapsulation layer 5 is a single-layer structure. The material of the encapsulation layer 5 includes the encapsulation material and the functional material 7. The functional material 7 is an electrically conductive material, an antistatic material, a high dielectric material or a combination thereof. The surface resistance of the encapsulation layer 5 is 10⁴-10¹¹Ω. The dielectric strength of the encapsulation layer 5 increases to achieve the antistatic effect.

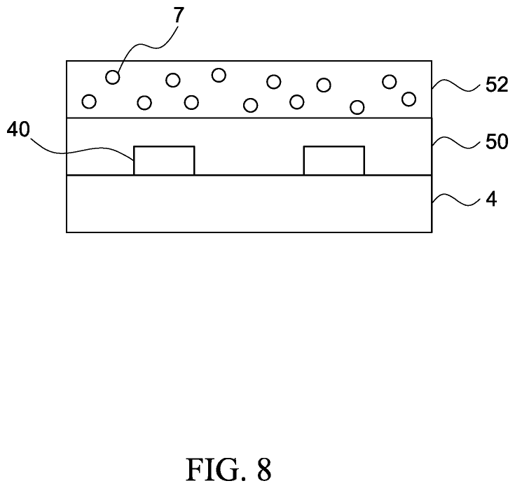

Referring to FIG. 8, in a sixth embodiment of the present invention, the encapsulation layer 5 is a double-layer structure, including a first encapsulation layer 50 and a second encapsulation layer 52. The second encapsulation layer 52 is disposed on the upper surface of the first encapsulation layer 50. The material of the first encapsulation layer 50 is the encapsulation material. The material of the second encapsulation layer 52 includes the encapsulation material and the functional material 7. The functional material 7 is an electrically conductive material, an antistatic material, a high dielectric material or a combination thereof. The surface resistance of the encapsulation layer 5 is 10⁴-10¹¹Ω. The surface resistance of the encapsulation layer 5 refers to the surface resistance of the second encapsulation layer 52, which increases the dielectric strength of the encapsulation layer 5 to achieve the antistatic effect.

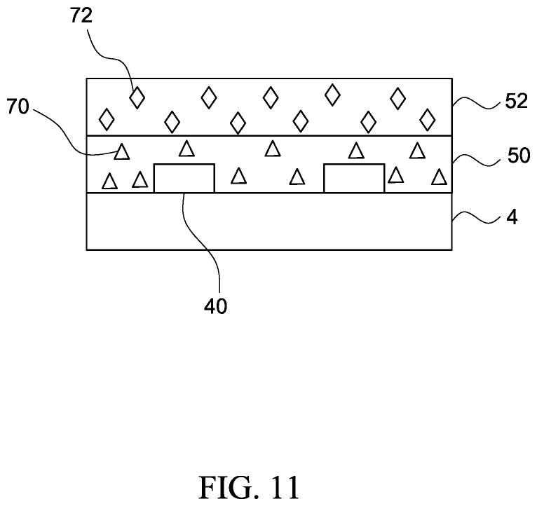

Referring to FIG. 11, in a seventh embodiment of the present invention, the encapsulation layer 5 is a double-layer structure, including a first encapsulation layer 50 and a second encapsulation layer 52. The second encapsulation layer 52 is disposed on the upper surface of the first encapsulation layer 50. The material of each of the first encapsulation layer 50 and the second encapsulation layer 52 includes the encapsulation material and the functional material 7. The functional material 7 of the first encapsulation layer 50 is defined as a first functional material 70. The functional material 7 of the second encapsulation layer 52 is defined as a second functional material 72. The first functional material 70 and the second functional material 72 are different materials. The first functional material 70 is a high dielectric material. The second functional material 72 is an antistatic material. The surface resistance of the encapsulation layer 5 is 10⁴-10¹¹Ω. The surface resistance of the encapsulation layer 5 refers to the surface resistance of the second encapsulation layer 52. In the seventh embodiment, the encapsulation layer 5 has the antistatic function and high dielectric strength function, so as to further strengthen the protection of the micro light-emitting diode display.

In the fifth embodiment, the sixth embodiment and the seventh embodiment of the present invention, the functional material may be a metal material, graphene, carbon nanotubes, carbon black, electrically conductive polymer, metal oxide or a mixture thereof. The metal material may be gold, silver, copper, molybdenum or other metals. The electrically conductive polymer may be poly(3,4-ethylenedioxythiophene) polystyrene sulfonate. The metal oxide may be zirconium oxide (ZrO₂), indium oxide (In₂O₃), zinc oxide (ZnO), tin oxide (SnO₂), titanium oxide (TiOx). The antistatic material may be cationic antistatic agent, anionic antistatic agent or amphoteric antistatic agent. The high dielectric material may be zinc oxide, silicon dioxide, titanium dioxide, zirconium oxide, barium sulfate, barium titanate, calcium carbonate or a mixture thereof. The encapsulation layer 5 of the fifth embodiment includes 0.01-10 wt % the functional material 7. The second encapsulation layer 52 of the sixth embodiment includes 0.01-10 wt % the functional material 7. In the seventh embodiment, the first encapsulation layer 50 includes 0.01-10 wt % the first functional material 70, and the second encapsulation layer 52 includes 0.01-10 wt % the second functional material 72. “wt %” stands for mass percentage concentration. When the functional material 7 is an electrically conductive material, a high dielectric material or a combination thereof, the functional material 7 is granular. The particle size of the functional material 7 is between 1 and 1000 nanometers. The antistatic material may be solid or liquid. The refractive index of the functional material 7 is greater than 2. The refractive index of the first encapsulation layer 50 of the sixth embodiment is between 1.4 and 1.7. The refractive index of the encapsulation layer 5 of the fifth embodiment, the refractive index of the second encapsulation layer 52 of the sixth embodiment, the refractive index of the first encapsulation layer 50 of the seventh embodiment and the refractive index of the second encapsulation layer 52 of the seventh embodiment are all between 1.6 and 2.0. The encapsulation material of the first encapsulation layer 50 and the encapsulation material of the second encapsulation layer 52 are different materials. The refractive index of the encapsulation material of the first encapsulation layer 50 is greater than the refractive index of the encapsulation material of the second encapsulation layer 52. In the sixth embodiment, the refractive index of the first encapsulation layer 50 is greater than the refractive index of the second encapsulation layer 52. In the seventh embodiment, the refractive index of the first encapsulation layer 50 is greater than the refractive index of the second encapsulation layer 52. By setting the refractive index for the encapsulation layer 5 of the fifth embodiment, the encapsulation layer 5 of the sixth embodiment and the encapsulation layer 5 of the seventh embodiment, the total reflection that occurs when the light generated by the light-emitting elements 40 hits the encapsulation layer 5 of the fifth embodiment, the encapsulation layer 5 of the sixth embodiment or the encapsulation layer 5 of the seventh embodiment can be reduced. The total reflection generated when the light generated by the light-emitting elements 40 penetrates the encapsulation layer 5 of the fifth embodiment, the encapsulation layer 5 of the sixth embodiment or the encapsulation layer 5 of the seventh embodiment can be reduced, thereby reducing the light loss caused by the total reflection and improving the light extraction efficiency of the micro light-emitting diode display is achieved.

In the fifth embodiment, the sixth embodiment and the seventh embodiment of the present invention, the outer layer of the high dielectric material may be further doped with the electrically conductive material, so as to further improve the conductivity and further strengthen the protection of the micro light-emitting diode display.

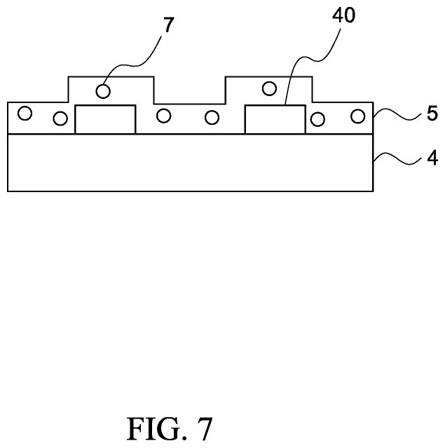

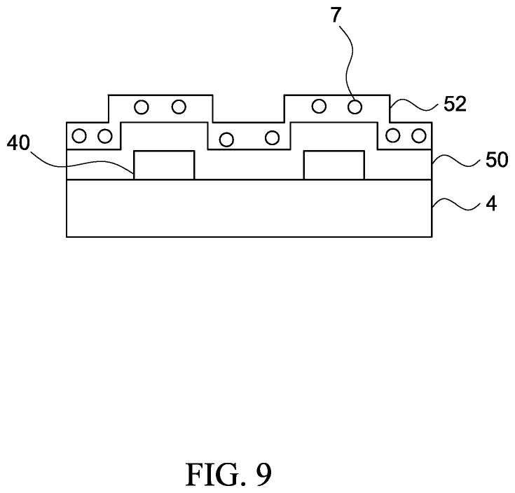

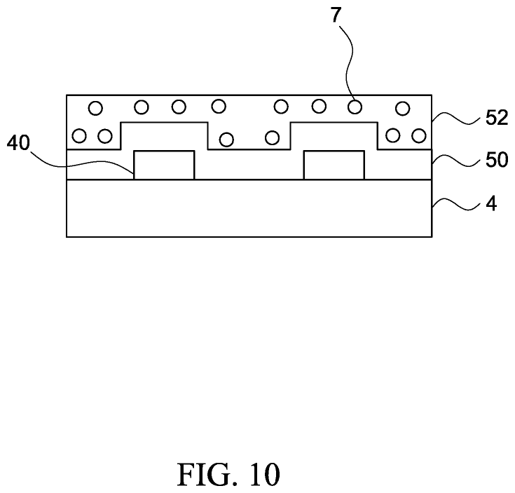

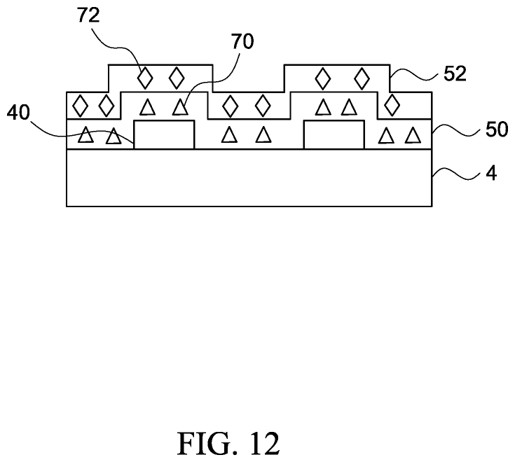

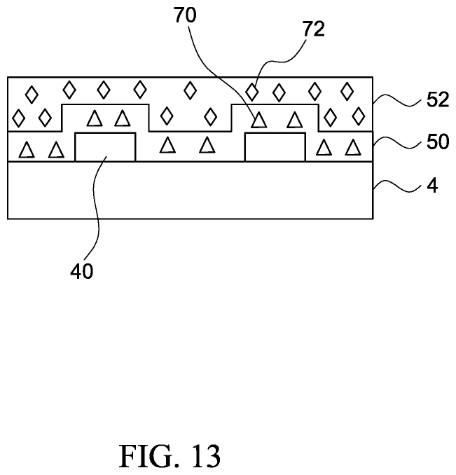

Referring to FIG. 7, in the fifth embodiment of the present invention, the upper surface of the encapsulation layer 5 may further include a plurality of microstructures. Referring to FIG. 9, in the sixth embodiment of the present invention, the first encapsulation layer 50 and the second encapsulation layer 52 may further include a plurality of microstructures. Referring to FIG. 10, in the sixth embodiment of the present invention, the first encapsulation layer 50 further includes a plurality of microstructures, and the second encapsulation layer 52 is a leveling layer. Referring to FIG. 12, in the seventh embodiment of the present invention, the first encapsulation layer 50 and the second encapsulation layer 52 each further include a plurality of microstructures. Referring to FIG. 13, in the seventh embodiment of the present invention, the first encapsulation layer 50 further includes a plurality of microstructures, and the second encapsulation layer 52 is a leveling layer. The fifth embodiment is taken as an example for the method to form the plurality of microstructures. In the fifth embodiment, the upper surface of the encapsulation layer 5 further includes a plurality of microstructures. The preparation method for the upper surface of the encapsulation layer 5 to have a plurality of microstructures may use nanoimprinting technology. The steps of nanoimprint technology includes: providing a nanoimprint mold with a pre-set microstructure pattern in advance; adding the encapsulation material and the functional material 7 to form a mixture that are evenly mixed; using the nanoimprint mold to shape the mixture for the upper surface of the mixture to form a plurality of microstructures; heating and pressurizing the mixture for curing and shaping; demoulding to obtain the encapsulation layer 5 after the temperature to cool down. The upper surface of the encapsulation layer 5 includes a plurality of microstructures.

In the first to seventh embodiments of the present invention, the encapsulating material may be thermosetting resin or photocurable resin, such as epoxy resin, silicone resin, silicone, acrylic resin or a mixture thereof. The material of the metal wires may be a stretch-proof metal. The stretch-proof metal may be gold, silver, copper, molybdenum, aluminum or other metals. In one embodiment of the present invention, the metal wires may be pre-strained, so as to offset the length change caused by stretching. The material of the flexible substrate 3 may be polyimide (PI), polyethylene naphthalate (PEN), polyethylene terephthalate (PET), or a combination thereof. The light-emitting elements 40 may be light-emitting diodes, mini light-emitting diodes (Mini LED), micro light-emitting diodes (Micro LED) or organic light-emitting diodes (OLED).

In one embodiment of the present invention, the technical features of the electrically conductive material layer 6 and the functional material 7 of the encapsulation layer 5 of the present invention are combined, so as to prevent the charges accumulated in the support layer 1 and the encapsulation layer 5 and to strength the protection of the micro light-emitting diode display.

In the eighth embodiment of the present invention, the micro light-emitting diode display is as shown in the fifth embodiment, and formula 1, formula 2, formula 3, formula 4, formula 5, formula 6, formula 7 and formula 8 are proposed. Formulas 1-8 represent the mass percent concentration (wt %) of the functional material 7 of the encapsulation layer 5, respectively. By comparing the brightness of the light generated by the micro light-emitting diode display prepared by formulas 1 to 8 with the brightness of the light generated by the micro light-emitting diode display that does not include the functional material 7, the brightness enhancement ratio is obtained. The unit of brightness enhancement ratio is expressed in %. Formula 1, the encapsulation layer 5 includes 0.10 wt % the functional material 7. Formula 2, the encapsulation layer 5 includes 0.15 wt % the functional material 7. Formula 3, the encapsulation layer 5 includes 0.20 wt % the functional material 7. Formula 4, the encapsulation layer 5 includes 0.25 wt % the functional material 7. Formula 5, the encapsulation layer 5 includes 0.30 wt % the functional material 7. Formula 6, the encapsulation layer 5 includes 0.50 wt % the functional material 7. Formula 7, the encapsulation layer 5 includes 0.99 wt % the functional material 7. Formula 8, the encapsulation layer 5 includes 1.20 wt % the functional material 7. The functional material 7 of formula 1-8 is zirconium oxide. The experimental results of the eighth embodiment are shown in Table 1 below. The experimental results show that as the mass percent concentration of the functional material 7 of the encapsulation layer 5 increases, the brightness enhancement ratio increases. In addition to the technical effect of antistatic, the present invention can improve the light extraction efficiency of the light generated by the micro light-emitting diode display.

TABLE 1

| functional material (wt %) | brightness enhancement ratio (%) |
|---|---|
| 0.10 | 0.5 |
| 0.15 | 1.3 |
| 0.20 | 4.9 |
| 0.25 | 9.3 |
| 0.30 | 18.3 |
| 0.50 | 33.3 |
| 0.99 | 44.0 |
| 1.20 | 58.7 |

In the ninth embodiment of the present invention, for the micro light-emitting diode display prepared by formula 1, formula 4, formula 7 and formula 8 proposed in the eighth embodiment, the measurement of the surface resistance of the encapsulation layer 5 is performed. The unit of the surface resistance is (2. Furthermore, taking the micro light-emitting diode display as shown in the fifth embodiment, formula 9 is further proposed. Formula 9, the encapsulation layer 5 includes 3.00 wt % the functional material 7. The functional material 7 of formula 9 is zirconium oxide. In the ninth embodiment, the measurement of the surface resistance of the micro light-emitting diode display prepared by formula 9 is performed. The unit of the surface resistance is (2. The experimental results of the ninth embodiment are shown in Table 2 below. The experimental results show that as the mass percent concentration of the functional material 7 of the encapsulation layer 5 increases, the surface resistance of the encapsulation layer 5 will decrease accordingly.

TABLE 2

| functional material (wt %) | surface resistance (Ω) |
|---|---|
| 0.10 | >1.06 × 10¹² |
| 0.25 | 5.8 × 10¹¹~7.8 × 10¹¹ |
| 0.99 | 5.3 × 10¹⁰~8.2 × 10¹⁰ |
| 1.20 | 1.2 × 10¹⁰~5.0 × 10¹⁰ |
| 3.00 | 5.7 × 10⁸~5.8 × 10⁸ |

To sum up, the micro light-emitting diode display provided by the present invention can prevent the accumulation of static electricity and solve the problem that the conventional micro light-emitting diode display is susceptible to electrostatic breakdown, causing component abnormalities or component damage. Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A micro light-emitting diode display, comprising a support layer, an optical adhesive layer, a flexible substrate, a flexible thin film transistor array module, and an encapsulation layer; the optical adhesive layer being disposed on an upper surface of the support layer, the flexible substrate being disposed on an upper surface of the optical adhesive layer, the flexible thin film transistor array module being disposed on an upper surface of the flexible substrate, the encapsulation layer covering an upper surface of the flexible thin film transistor array module, characterized in that: the micro light-emitting diode display further comprises at least one electrically conductive material layer disposed on one side away from the flexible thin film transistor array module.

2. The micro light-emitting diode display as claimed in claim 1, wherein the electrically conductive material layer is disposed between the optical adhesive layer and the flexible substrate, and the electrically conductive material layer has a sheet resistance of 10-10⁶Ω/□.

3. The micro light-emitting diode display as claimed in claim 1, wherein the electrically conductive material layer is disposed between the support layer and the optical adhesive layer, and the electrically conductive material layer has a sheet resistance of 10-10⁶Ω/□.

4. The micro light-emitting diode display as claimed in claim 1, wherein the electrically conductive material layer is disposed on part of the upper surface of the support layer, and the electrically conductive material layer has a sheet resistance of 10⁶-10¹²Ω/□.

5. The micro light-emitting diode display as claimed in claim 1, wherein the at least one electrically conductive material layer includes two electrically conductive material layers, i.e., a first electrically conductive material layer and a second electrically conductive material layer, wherein the first electrically conductive material layer is disposed on a lower surface of the support layer; wherein the second electrically conductive material layer is disposed between the support layer and the optical adhesive layer, and the first electrically conductive material layer and the second electrically conductive material layer each have a sheet resistance of 10⁶-10¹²Ω/□.

6. The micro light-emitting diode display as claimed in claim 1, wherein the electrically conductive material layer is made of indium tin oxide, aluminum-doped zinc oxide, fluorine-doped tin oxide, silver nanowire, carbon nanotube, electrically conductive polymer or a combination thereof, and the electrically conductive polymer is poly(3,4-ethylenedioxythiophene) polystyrene sulfonate.

7. A micro light-emitting diode display, comprising a support layer, an optical adhesive layer, a flexible substrate, a flexible thin film transistor array module, and an encapsulation layer; the optical adhesive layer being disposed on an upper surface of the support layer, the flexible substrate being disposed on an upper surface of the optical adhesive layer, the flexible thin film transistor array module being disposed on an upper surface of the flexible substrate, the encapsulation layer covering an upper surface of the flexible thin film transistor array module, characterized in that: the encapsulation layer includes an encapsulation material and at least one functional material, wherein the functional material is an electrically conductive material, an antistatic material, a high dielectric material or a combination thereof.

8. The micro light-emitting diode display as claimed in claim 7, wherein when the functional material is the electrically conductive material, the high dielectric material or a combination thereof, the functional material is granular, and the functional material has a particle size between 1 and 1000 nanometers.

9. The micro light-emitting diode display as claimed in claim 7, wherein the functional material has a refractive index greater than 2.

10. The micro light-emitting diode display as claimed in claim 7, wherein the encapsulation layer is a single-layer structure, the encapsulation layer includes the encapsulation material and the functional material, and the encapsulation layer has a surface resistance of 10⁴-10¹¹Ω.

11. The micro light-emitting diode display as claimed in claim 10, wherein the encapsulation layer includes 0.01-10 wt % the functional material.

12. The micro light-emitting diode display as claimed in claim 10, wherein the encapsulation layer has a refractive index between 1.6 and 2.0.

13. The micro light-emitting diode display as claimed in claim 7, wherein the encapsulation layer is a double-layer structure including a first encapsulation layer and a second encapsulation layer; wherein the second encapsulation layer is disposed on an upper surface of the first encapsulation layer, wherein the material of the first encapsulation layer is the encapsulation material; wherein the material of the second encapsulation layer includes the encapsulation material and the functional material; wherein the encapsulation layer has a surface resistance of 10⁴-10¹¹Ω.

14. The micro light-emitting diode display as claimed in claim 13, wherein the first encapsulation layer has a refractive index between 1.4 and 1.7.

15. The micro light-emitting diode display as claimed in claim 13, wherein the second encapsulation layer has a refractive index between 1.6 and 2.0.

16. The micro light-emitting diode display as claimed in claim 13, wherein the second encapsulation layer includes 0.01-10 wt % the functional material.

17. The micro light-emitting diode display as claimed in claim 7, wherein the encapsulation layer is a double-layer structure including a first encapsulation layer and a second encapsulation layer; wherein the second encapsulation layer is disposed on an upper surface of the first encapsulation layer, wherein each of the material of the first encapsulation layer and the material of the second encapsulation layer is composed of the encapsulation material and the functional material, wherein the functional material of the first encapsulation layer is defined as a first functional material; wherein the functional material of the second encapsulation layer is defined as a second functional material; wherein the first functional material and the second functional material are different materials; wherein the encapsulation layer has a surface resistance of 10⁴-10¹¹Ω.

18. The micro light-emitting diode display as claimed in claim 17, wherein the first encapsulation layer has a refractive index between 1.6 and 2.0.

19. The micro light-emitting diode display as claimed in claim 17, wherein the second encapsulation layer has a refractive index between 1.6 and 2.0.

20. The micro light-emitting diode display as claimed in claim 17, wherein when the functional material is the electrically conductive material, the high dielectric material or a combination thereof, the first encapsulation layer includes 0.01-10 wt % the first functional material, and the second encapsulation layer includes 0.01-10 wt % the second functional material.
